(19) United States
(12) Patent Application Publication
(10) Pub. No.: US 2024/0160688 A1
(43) Pub. Date: May 16, 2024

(54) STEPWISE SUPERPOSITION-BASED FOURIER TRANSFORM DIFFERENTIAL METHOD

(71) Applicant: FU JIAN JIA PU XIN KE TECHNOLOGY CO.LTD, Fuzhou, Fujian (CN)

(72) Inventor: Shuping CHEN, Ontario (CA)

(73) Assignee: FU JIAN JIA PU XIN KE TECHNOLOGY CO.LTD, Fuzhou, Fujian (CN)

(21) Appl. No.: 17/776,251

(22) PCT Filed: Sep. 26, 2021
(86) PCT No.: PCT/CN2021/120552

§ 371 Date: May 12, 2022

(30) Foreign Application Priority Data
May 7, 2021 (CN) 202110492674.8

(51) Int. Cl. G06F 17/14; G01D 1/10

(52) U.S. Cl. CPC G06F 17/141; G01D 1/10

(57) ABSTRACT

The invention relates to a stepwise superposition-based Fourier transform differentiation method, which comprises the following steps: S1, sampling an analytic signal in a finite time domain, converting the analytic signal into a discrete spectrum, and identifying spectral peak vertexes through a differential curve of the spectrum; S2, superposing the peak vertexes in the spectrum in a stepped manner according to the principle of superposition-based Fourier transform; and S3, differentiating the spectrum after the stepwise superposition to obtain a stepwise superposition-based Fourier transform differential spectrum or image. The invention not only potently improves the resolution and sensitivity, but also greatly saves computing time.

### BACKGROUND OF THE INVENTION

### 1. Technical Field

The invention relates to the field of spectral and imaging signal processing, in particular to a stepwise superposition-based Fourier transform differential method.

### 2. Description of Related Art

An analytic signal s(t) which periodically varies with time r can be converted into a spectrum S(ω) regarding frequency c by Fourier transform according to a general mathematical expression:

$$S ( ω ) = \frac{1}{π} {\int }_{- ∞}^{∞} s ( t ) {e}^{- i ω t} dt .$$

The spectrum S(ω) can be converted back to the original analytic signal s(t) through inverse Fourier transform:

$$s ( t ) = \frac{1}{π} {\int }_{- ∞}^{∞} s ( ω ) {e}^{- i ω t} d ω .$$

The above Fourier transform integration is multiplied by a complex exponential function e^{-iωt} or e^{iωt}, where i=\sqrt{−1}.

Fourier transform of harmonic waves generates three basic peak shapes with symmetrical profiles: absorption peak shape, dispersion peak shape and magnitude peak shape. Practical signals usually have an attenuation effect, and a basic peak shape from Fourier transform evolves into a Lorentz peak shape, or is comparable to a Lorentz peak shape (such as a Gaussian peak shape and a Voigt peak shape), which is also symmetrical like the three basic peak shapes. In the prior art, implementation of the superposition regarding the symmetrical profiles is complicated and time-consuming, which is similar to a curve fitting method in spectroscopy. It asks some prior knowledge to superimpose limited signal data and relatively simple images. Generally speaking, the key to improving the analytical performance of the spectroscopy and imaging technology using Fourier transform is how to effectively detect weak signals and deconvolute overlapping spectral peaks.

### BRIEF SUMMARY OF THE INVENTION

In view of this, the purpose of the invention is to provide a stepwise superposition Fourier transform differential method, which not only potently improves the resolution and sensitivity, but also greatly saves computing time.

In order to achieve the above purpose, the invention adopts the following technical solution:

A stepwise superposition-based Fourier transform differential method comprises:
S1, sampling an analytic signal in a finite time domain, converting the analytic signal into a discrete spectrum, and identifying positions of spectral peak vertexes through a differential curve of the spectrum;
S2, superposing the peak vertexes in the spectrum in a stepped manner according to the principle of superposition-based Fourier transform; and
S3, differentiating the spectrum after the stepwise superposition to obtain a stepwise superposition-based Fourier transform differential spectrum or image.

Further, in the Step S1,
the analytic signal s(t) is discretized in a measurement period so as to take N samples, s(0), s(1), s(2), . . . , s(N−1), N frequency spectrum data S(0), S(1), S(2), . . . , S(N−1) are obtained by discrete Fourier transform, and the Fourier transform matrix is expressed as follows:

$$[ \begin{matrix}S ( 0 ) \\ S ( 1 ) \\ S ( 2 ) \\ ⋮ \\ S ( N - 1 )\end{matrix} ] = [ \begin{matrix}1 & 1 & 1 & … & 1 \\ 1 & W & {W}^{2} & … & {W}^{N - 1} \\ 1 & {W}^{2} & {W}^{4} & … & {W}^{N - 2} \\ ⋮ & ⋮ & ⋮ & ⋱ & ⋮ \\ 1 & {W}^{N - 1} & {W}^{N - 2} & … & W\end{matrix} ] [ \begin{matrix}s ( 0 \\ s ( 1 ) \\ s ( 2 ) \\ ⋮ \\ s ( N - 1 )\end{matrix} ] \qquad ( 1 )$$

where W=exp(−i2π/N);
the Fourier transform spectrum S(ω) is multiplied by a diagonal matrix diag[aₖ];

$$diag [ {a}_{k} ] \times [ S ( ω ) ] = [ \begin{matrix}0 & 0 & 0 & … & 0 & … & 0 \\ 0 & {a}_{1} & 0 & … & 0 & … & 0 \\ 0 & 0 & {a}_{2} & … & 0 & … & 0 \\ ⋮ & ⋮ & ⋮ & ⋱ & ⋮ & … & ⋮ \\ 0 & 0 & 0 & … & {a}_{k} & … & 0 \\ ⋮ & ⋮ & ⋮ & … & ⋮ & ⋱ & ⋮ \\ 0 & 0 & 0 & … & 0 & … & {a}_{N - 1}\end{matrix} ] [ \begin{matrix}S ( 0 ) \\ S ( 1 ) \\ S ( 2 ) \\ ⋮ \\ S ( k ) \\ ⋮ \\ S ( N - 1 )\end{matrix} ] \qquad ( 3 )$$

where if there are m overlapping peaks, the value of the diagonal element aₖ is 2n, n=0, 1, 2, . . . , m;
a stepwise superposition diagonal matrix is further written as:

$$diag [ {a}_{kk} ] = \begin{matrix} & & & {ω}_{1} & & & {ω}_{2} & & & {ω}_{3} & & & {ω}_{4} & & & & & \\ [ 0 & … & 0 & 2 & … & 2 & 4 & … & 4 & 6 & … & 6 & 8 & … & 8 & 0 & … & 0 ]\end{matrix} \qquad ( 4 )$$

peak vertexes ω₁, ω₂, ω₃ and ω₄ in a spectrum are located through discrimination of its second derivative.

Further, in the Step S2,
it is assumed that there are N overlapping peaks in the spectrum, that is, F₁, F₂, F₃, . . . , F_{N′}, the first peak F₁ is located on a zero step, whose peak intensity is multiplied by 2 according to a right superposition function, and the baseline is still the original spectral peak baseline 0; the peak intensity of the second peak F₂ is multiplied by 4 to rise to a first step, the third peak F₃ is multiplied by 6 to rise to a second step, . . . , the N^{th} peak F_{N} is multiplied by 2N to rise to a (N−1)^{th} step. After it comes to the last overlapping peak, returning to the zero step is conducted immediately; and then, the spectrum after the stepwise superposition is differentiated, so that the baseline of the superposition spectral line of the second peak returns to the first step after differentiation, which is marked as baseline 1; and so on to mark the remaining baselines. Then, the baselines are linked together to form a stepwise superposition-based Fourier transform differential spectrum.

Further, in the Step S3,
it is assumed that a peak vertex of the k^{th} overlapping peak is located at S(ωₖ), which becomes 2k^{S(ω}^{ₖ}⁾ after the stepwise superposition, and according to the differential rule of multiplied functions:

$$\frac{Δ [ 2 k S ( {ω}_{k} ) ]}{Δ ω} = \frac{Δ ( 2 k )}{Δ ω} S ( {ω}_{k} ) + 2 k \frac{Δ [ S ( {ω}_{k} ) ]}{Δ ω} = 2 S ( {ω}_{k} ) + 2 k \frac{Δ [ S ( {ω}_{k} ) ]}{Δ ω} \qquad ( 5 )$$

where Δ(2k)/Δω=2k−2(k−1)=2, which is equal to the difference from the previous (k−1)^{th} step; for all the following peak values S(W) of the same step, 2k is a constant, that is, Δ(2k)=0:

$$\frac{Δ [ 2 k S ( ω ) ]}{Δ ω} = 2 k \frac{Δ [ S ( ω ) ]}{Δ ω} \qquad ( 6 )$$

(5) and (6) indicate that all points of the spectrum except the peak vertexes are processed into a spectral background by the differentiation.

Compared with the prior art, the invention has the following beneficial effects:

1. The invention not only preserves the effect of doubling the peak value by a superposition-based Fourier transform method, but also effectively enhances the resolution due to benefits of the differential/derivative spectroscopy, the analytical sensitivity and deconvolution capability of Fourier transform are improved.

2. The invention can be applied to interferometers including infrared spectroscopy and magnetic resonance imaging instruments using the Fourier transform technology. It can treat each dimension of multidimensional spectra and images in the same way, so as to quickly upgrade performance of the conventional spectra and images.

### BRIEF DESCRIPTION OF THE SEVERAL VIEWS OF THE DRAWINGS

FIG. 1 is a diagram of overlapping peaks of a conventional Fourier transform spectrum according to an embodiment of the invention;

FIG. 2 is a diagram of doubled resolution and peak intensity of the overlapping peaks in FIG. 1 after superposition-based Fourier transform is implemented;

FIG. 3 is a diagram of the stepwise superposition principle of the invention;

FIG. 4 is a diagram of high resolution and high sensitivity of the overlapping peaks in FIG. 1 after a stepwise superposition-based Fourier transform differentiation method of the invention is implemented;

FIG. 5 is a comparison of infrared spectra of 1550-1650 cm⁻¹ and 2970-3200 cm⁻¹ wavebands in a polystyrene fingerprint region obtained by using a stepwise superposition-based Fourier transform differential technique of the invention and a conventional Fourier transform technique according to an embodiment of the invention;

FIG. 6 is a comparison of phenyl hydrogen nuclear magnetic resonance spectra of ethylbenzene obtained by using a stepwise superposition-based Fourier transform differential technique of the invention and a conventional Fourier transform technique according to an embodiment of the invention;

FIG. 7 is a magnetic resonance image (pixel 512×512) of an artificial membrane obtained with a magnetic field of 3 T according to an embodiment of the invention;

FIG. 8 is a diagram showing that stepwise superposition and a differential curve are applied to the original image of FIG. 7;

FIG. 9 is an image of the artificial membrane of FIG. 7 after a stepwise superposition-based Fourier transform differential technique of the invention is applied according to an embodiment of the invention;

FIG. 10 is a conventional Fourier transform-based magnetic resonance medical image from a volunteer's head obtained with a magnetic field of 1.5 T according to an embodiment of the invention; and

FIG. 11 is an image of the head image in FIG. 10 after a stepwise superposition-based Fourier transform differential technique of the invention is applied according to an embodiment of the invention.

### DETAILED DESCRIPTION OF THE INVENTION

The invention will be further described below with reference to the accompanying drawings and embodiments.

The invention provides a stepwise superposition-based Fourier transform differential method, comprising:
S1, sampling an analytic signal in a finite time domain, converting the analytic signal into a discrete spectrum, and identifying spectral peak vertexes through a differential curve of the spectrum;
S2, superposing the peak vertexes in the spectrum in a stepped manner according to the principle of superposition-based Fourier transform; and
S3, differentiating the spectrum after the stepwise superposition to obtain a stepwise superposition-based Fourier transform differential spectrum or image.

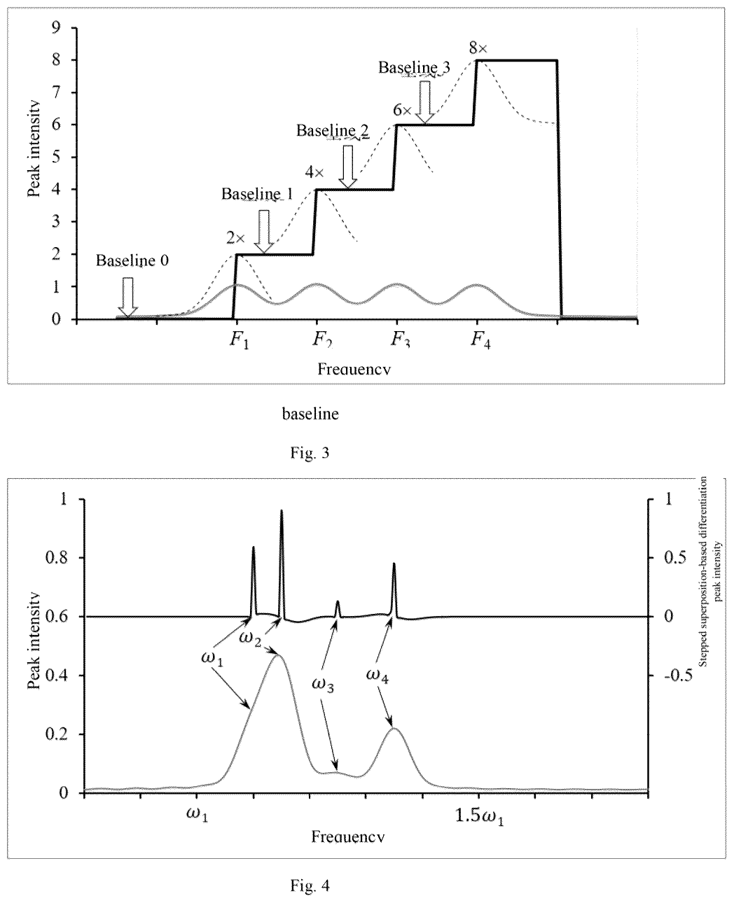

In this embodiment, referring to FIG. 3, four overlapping peaks F₁, F₂, F₃ and F₄ (gray curves at the bottom of the figure) are used to illustrate procedures of the stepwise superposition-based differentiation method; the first peak F₁ is located on a zero step, and its left half peak belongs to a zero baseline (marked as baseline 0), and its right half peak is multiplied by 2 according to a right superposition function; because the peaks overlap one another, the left half peak of the second peak F₂ is also multiplied by 2 and located on a first step (if the four peaks are too crowded, the front overlapping portion of the peak F₁ or even F₄ will be partially taken to the first step), the peak intensity of the right half is multiplied by 4, and the first half of the third peak F₃ is led to a second step at the same time; and according to this incremental manner, the right half of the third peak F₃ is multiplied by 6 to rise to the second step, and the right half of the fourth peak F₄ is multiplied by 8 to rise to a third step. When it comes to the last overlapping peak, the step value should immediately return to baseline 0. Then the spectrum after the stepwise superposition is differentiated, so that the baseline of the superposition spectral line of the second peak returns to the first step (baseline 1) after differentiation according to the arrow direction in FIG. 3; similarly, the baseline of the third peak returns to the second step, marked as baseline 2; the baseline of the fourth peak returns to the third step, marked as baseline 3; and then the baselines are connected to form a stepwise superposition-based Fourier transform differential spectrum; that is, the spectral peak vertexes are subjected to stepwise superposition-based differentiation, while the—conventional differential spectrum becomes the baseline. Compared with a simple superposition-based Fourier transform technique, the invention preserves the effect of doubling the peak intensity, and potently improves the spectral resolution and sensitivity through differentiation.

Preferably, in this embodiment, it is assumed that an analytic signal s(t) of one time domain t is intercepted to N separate signals [s(0), s(1), s(2), . . . , s(k), . . . , s(N−1)], a set of N frequency domain data S(ω)=[S(0), S(1), S(2), . . . , S(k), . . . , S(N−1)] is obtained by Fourier transform, and the latter can be converted back into the time signal s(t) by inverse Fourier transform, which is mathematically simply expressed as:

$$s ( t ) = [ \begin{matrix}s ( 0 ) \\ s ( 1 ) \\ s ( 2 ) \\ ⋮ \\ s ( k ) \\ ⋮ \\ s ( N - 1 )\end{matrix} ] \begin{matrix}{\to }^{Fourier transform} & \\ & S ( ω ) = \\ {←}_{Inverse Fourier \\ transform} & \end{matrix} [ \begin{matrix}S ( 0 ) \\ S ( 1 ) \\ S ( 2 ) \\ ⋮ \\ S ( k ) \\ ⋮ \\ S ( N - 1 )\end{matrix} ] \qquad ( 2 )$$

Fourier transform spectroscopy and imaging have several wellborn characteristics: analytic signals suitable for Fourier transform are simple signals which vary periodically, such as interference signals generated by a laser light source of an infrared spectrometer, nuclear spin free induction decay signals excited by radio frequency waves in a nuclear magnetic resonance spectrometer, and hydrogen nuclear magnetic resonance signals of water molecules in human tissue measured through magnetic resonance medical imaging. The peak width of the Fourier transform spectrum is not relevant with the signal frequency, but mainly depends on the measurement time and attenuation coefficient of the analytic signals. Therefore, under the same circumstances, all peaks except the peak height should have the same peak shape; for example, the Fourier transform waveforms of resonance attenuation signals are all in the Lorentz shape.

The Fourier transform spectrum S(m) is multiplied by a diagonal matrix diag[aₖ]:

$$diag [ {a}_{k} ] \times [ S ( ω ) ] = [ \begin{matrix}0 & 0 & 0 & … & 0 & … & 0 \\ 0 & {a}_{1} & 0 & … & 0 & … & 0 \\ 0 & 0 & {a}_{2} & … & 0 & … & 0 \\ ⋮ & ⋮ & ⋮ & ⋱ & ⋮ & … & ⋮ \\ 0 & 0 & 0 & … & {a}_{k} & … & 0 \\ ⋮ & ⋮ & ⋮ & … & ⋮ & ⋱ & ⋮ \\ 0 & 0 & 0 & … & 0 & … & {a}_{N - 1}\end{matrix} ] [ \begin{matrix}S ( 0 ) \\ S ( 1 ) \\ S ( 2 ) \\ ⋮ \\ S ( k ) \\ ⋮ \\ S ( N - 1 )\end{matrix} ] \qquad ( 3 )$$

where if there are m overlapping peaks, the value of the diagonal element aₖ is 2n, n=0, 1, 2, . . . , m; and
a stepwise superposition diagonal matrix is further written as:

$$diag [ {a}_{k} ] = [ 0 … 0 {2}^{{ω}_{1}} … 2 {4}^{{ω}_{2}} … 4 {6}^{{ω}_{3}} … 6 {8}^{{ω}_{4}} … 80 … 0 ] \qquad ( 4 )$$

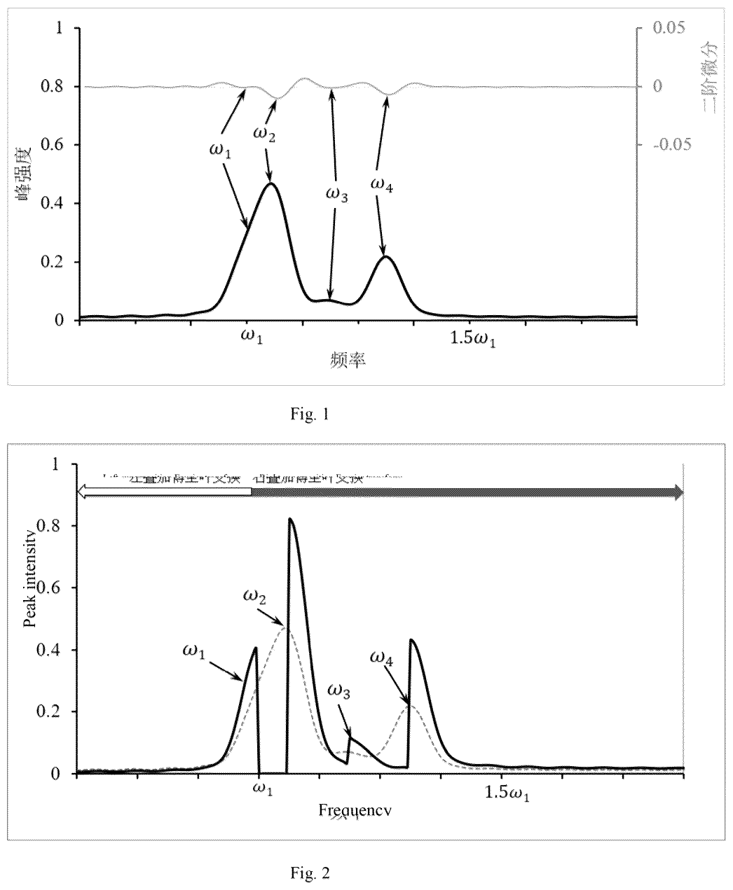

Peak vertexes ω₁, ω₂, w₃ and w₄, of the spectrum are easily located through discrimination of a second derivative (see FIG. 1), and stepwise superposition is conducted step by step according to the located peak vertexes: 2×1, 2×2, 2×3, 2×4 and so on. After stepwise superposition of the last overlapping peak, return to zero (baseline 0) as soon as possible to prevent their overlapping information from being carried to the following non-overlapping peaks. After the stepwise superposition spectrum generated by (3) is differentiated, the baseline of a high-step superposition peak just returns to the adjacent lower step.

It is assumed that a peak vertex of the k^{th} overlapping peak is located at S(ωₖ), which becomes 2k^{S(ω}^{ₖ}⁾ after the stepwise superposition, and according to the differential rule of multiplied functions:

$$\frac{Δ [ 2 k S ( {ω}_{k} ) ]}{Δ ω} = \frac{Δ ( 2 k )}{Δ ω} S ( {ω}_{k} ) + 2 k \frac{Δ [ S ( {ω}_{k} ) ]}{Δ ω} = 2 S ( {ω}_{k} ) + 2 k \frac{Δ [ S ( {ω}_{k} ) ]}{Δ ω} \qquad ( 5 )$$

where Δ(2k)/Δω=2k−2(k−1)=2, which is equal to the difference from the previous (k−1)^{th} step. For all the following peak values S(ω) of the same step, 2k is a constant, that is, Δ(2k)=0:

$$\frac{Δ [ 2 k S ( ω ) ]}{Δ ω} = 2 k \frac{Δ [ S ( ω ) ]}{Δ ω} \qquad ( 6 )$$

Equations (5) and (6) indicate that all points of the spectrum except the peak vertexes are processed into a spectral background—by the differentiation, so that a spectral peak can be accurately determined by using as little as three stepwise superposition-based Fourier transform differential data points. Generally, in discrete Fourier transform algorithm, Δω=1. These three points are composed of the last differential spectral point 2(k−1)Δ^{S(ω}^{ₖ}⁻¹⁾ of the previous step, the peak vertex 2^{S(ω}^{ₖ}⁾+2kΔ^{S(ω}^{ₖ}⁾, and the differential spectral point 2kΔ^{S(ω}^{ₖ}⁺¹⁾ of the same step immediately following the peak vertex.

Referring to FIG. 4, in this embodiment, four simulated overlapping peaks (the bottom gray spectrum) are successfully completely separated by the stepwise superposition-based Fourier transform method, and the intensity of each peak is doubled (the top black spectrum). A new Fourier transform spectrum is generated by connecting the baselines after step differentiation. Other than the peak intensity is doubled, —the sensitivity and resolution are overwhelmingly enhanced. The determination of the peak vertexes of the curve, stepwise superposition—and differentiation are simple for computers, so the stepwise superposition-based Fourier transform differential spectrum can be quickly and effectively obtained based on the conventional Fourier transform spectrum. The differential spectral background in FIG. 4 can also be flattened to a zero baseline, which makes the spectrum look neater. However, these differential backgrounds contain valuable information such as the overlapping degree of the spectral peaks and noise hidden under original spectral peaks, which can be used to calculate the true peak height of the overlapping peaks. Generally, a signal-to-noise ratio (SNR) is calculated by measuring a peak-to-peak value of a smooth baseline closest to the spectral peak which serves as background noise, rather than the real noise hidden under the peaks, and the stepwise superposition-based Fourier transform differential technique provides a possible way to measure the real background noise.

Differential spectroscopy has high sensitivity and deconvolution capability for overlapping peaks. The stepwise superposition-based Fourier transform differential technique of the invention maintains these two merits, and makes up for the shortcomings of conventional differential spectroscopy: irregular peak shapes and complicated evaluation of peak value. The Lorentz peak shape and peak height can be replaced by peak width W_{1/2} at half peak height in calculation of theoretical resolution. If a distance between two Fourier transform spectral peaks is D, their resolution Rs can be simply written as:

Rs=D/(2W_{1/2}) (7)

Taking an overlapping spectral band close to the Lorentz peak shape in FIG. 1 as an example. Table 1 lists the best scopes semi-quantitatively for a fast construction of the stepwise superposition-based Fourier transform differential spectrum and image.

TABLE 1

| | Signal-to | Intensity ratio | Derivatives |
|---|---|---|---|
| Resolution | Noise ratio | of 2 over- | required for peak |
| (Rs) | (SNR) | lapping peaks | identification |
| Rs ≥ 0.5 | ≥3 | ≥1% | 1^{st} & 2^{nd} derivatives |
| 0.35 ≤ | ≥9 | ≥5% | 1^{st}, 2^{nd} & 3^{rd} derivatives |
| Rs < 0.5 | | | |

The location of the Fourier transform spectral peaks needs to be supported by sufficient sampling data, and it is better to have more than 10 times of data points of Nyquist Criterion for semi-quantitative analysis. For overlapping spectral bands with resolution ≥0.5, a convex stagnation point, i.e., the peak vertex, of the spectral curve can be accurately located based on the first and second derivatives of the commonly used differential spectrum method. When the resolution between spectral peaks is less than 0.5 but greater than 0.35, slope change points (convex stagnation point and concave stagnation point) of the first derivative can be found based on the usual second and third derivatives so as to locate the peak vertex of the secondary peak.

Of course, it is unnecessary to confine the parameters listed in Table 1. For example, better quantitative results can be obtained by analyzing the asymmetry of the peaks and the overlapping degree, suppressing the background noise, and adopting a sampling frequency greater than 20 times of Nyquist Criterion, all of which require more analyses and computing time.

### Embodiment 1

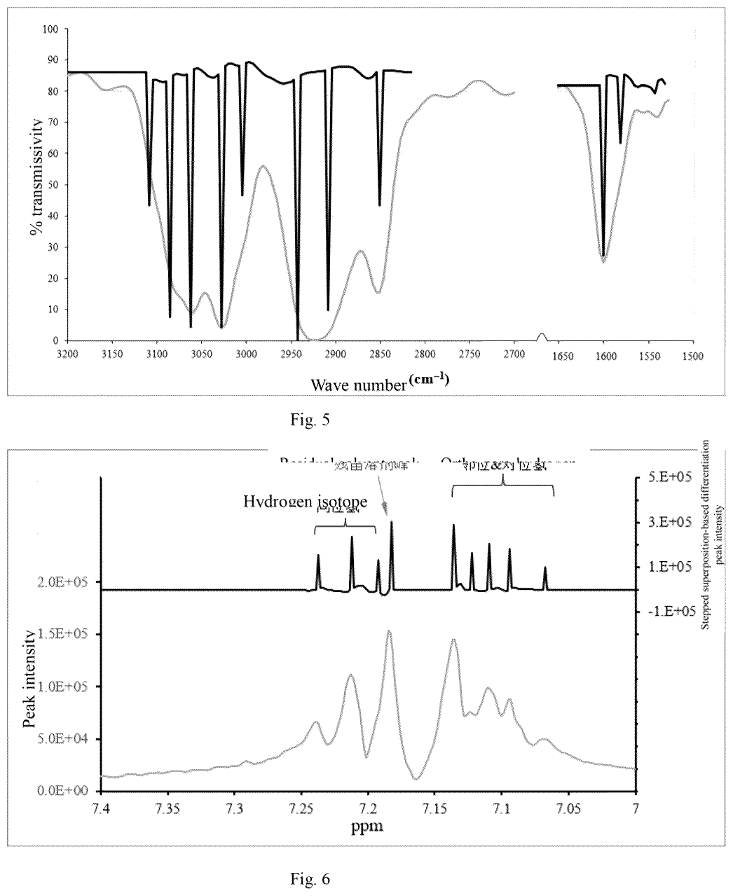

The embodiment provides a method for quickly obtaining high-resolution and high-sensitivity an infrared spectrum based on a stepwise superposition-based Fourier transform differential technique. In this embodiment, a Nicolet Protégé 460 commercial Fourier transform infrared spectrometer was used, and a He—Ne laser infrared light source with a wavelength of 632.8 nm (6.328×10⁻⁵ cm) was configured. A polystyrene Fourier transform infrared spectrum was obtained with a resolution of 16 cm⁻¹ at wavenumber spacing of 3.85 cm⁻¹ by moving an optical path of the interferometer in two directions by 3295 retardations and setting 709 wavenumber readings. The lower gray spectral line of FIG. 5 is a fingerprint region of a native polystyrene infrared spectrum. There are only four characteristic peaks in the wavenumber range of 2970-3200 cm⁻¹, which are 2854 cm⁻¹, 2924 cm⁻¹, 3028 cm⁻¹ and 3062 cm⁻¹. Only one characteristic peak appeared at wave-number 1601 cm⁻¹ in the range of 1550-1650 cm⁻¹. After implementing the stepwise (right) superposition-based Fourier transform differential technique of the invention, as shown by the upper black spectral line of FIG. 5, there are eight characteristic peaks in the wave-number range of 2970-3200 cm⁻¹, which are 2850.3 cm⁻¹, 2908.2 cm⁻¹, 2942.9 cm⁻¹, 3004.6 cm⁻¹, 3027.7 cm⁻¹, 3062.5 cm⁻¹, 3085.6 cm⁻¹ and 3108.7 cm⁻¹. Two characteristic peaks, 1581.4 cm⁻¹ and 1600.7 cm⁻¹, are clearly resolved in the wavenumber range of 1550-1650 cm⁻¹. Differential bulges accompanying the peaks with wavenumbers of 2850.3 cm⁻¹, 2908.2 cm⁻¹ and 2942.9 cm⁻¹ in FIG. 5 indicate that these three peaks (perhaps more peaks) overlap seriously. On the basis of the original data with the resolution of 16 cm⁻¹, an infrared spectrum obtained by implementing the stepwise superposition-based Fourier transform differential technology in the invention can be comparable nicely to a high-resolution 4 cm⁻¹ polystyrene Fourier transform infrared spectrum.

### Embodiment 2

The embodiment provides a method for quickly obtaining a high-resolution and high-sensitivity nuclear magnetic resonance spectrum based on a stepwise superposition-based Fourier transform differential technique. FIG. 6 compares the before and after effects of a 300 MHz hydrogen nuclear (¹H) nuclear magnetic resonance spectrum of the compound ethylbenzene obtained from a QE-300 nuclear magnetic resonance spectrometer manufactured by GE of the United States. The main instrumental parameters were: magnetic field intensity 7 T, dwell time 250 μs, scanning bandwidth 4000 Hz, bias frequency 1850 Hz, sampling time 0.512 s, sampling point spacing 1.95 Hz. By adding double zero fillings to free induction decay signals in two channels of nuclear magnetic resonance, the number of original data points is expanded from 2048 to 8192. The bottom solid gray line in FIG. 6 shows a 300 MHz conventional Fourier transform nuclear magnetic resonance spectrum of phenyl hydrogen of ethylbenzene. The spectrum ranges from 7 to 7.4 ppm, mainly distributed in two bands: phenyl ortho-para-hydrogen band (7.05 to 7.15 ppm) and phenyl meta-hydrogen band (7.16 to 7.26 ppm). Five overlapping peaks can barely be distinguished from the ortho-para-hydrogen band. Only three peaks in the meta-hydrogen band are visible. The upper black solid line spectrum in FIG. 6 is a stepwise superposition-based Fourier transform differential nuclear magnetic resonance spectrum generated by the stepwise (right) superposition-based Fourier transform differential technique of the invention. The invention not only completely distinguishes the five overlapping peaks of the ortho-para-hydrogen band, but also completely separates a solvent peak fused into the meta-hydrogen band. The spectrum obtained from the 300 MHz nuclear magnetic resonance spectrometer by the stepwise superposition-based Fourier transform differential technique is comparable to an ethylbenzene spectrum obtained from a 500 MHz nuclear magnetic resonance spectrometer, either in resolution or in sensitivity.

### Embodiment 3

In this embodiment, although Fourier transform magnetic resonance imaging is based on the principle of two-dimensional or three-dimensional space nuclear magnetic resonance, there are several significant differences from the above Fourier transform nuclear magnetic resonance spectrum.

(1) Spatial positions of pixels of the image are determined according to a sequence of measurement time, equivalent to nominal time domain analytic signals.

(2) Magnetic resonance imaging measures the nuclear spin resonance frequency of the same kind of nuclei (such as hydrogen nuclei of water molecules) in a three-dimensional gradient magnetic field. These frequency signals are arranged and stored with gradient zero as the center, and are called k-space, which nominally belongs to a frequency domain space.

(3) Therefore, the magnetic resonance image is transformed from the k-space by inverse Fourier transform. However, inverse Fourier transform and (positive) Fourier transform have many commonalities, for example, common techniques such as zero filling, interpolation and apodization for time domain signal treatment, are still effective for the k-space.

(4) Every pixel of a measured body part in magnetic resonance imaging is a “peak vertex” (pixels outside the body part are the background), so the pixels in each dimension are equivalent to overlapping “peaks” arranged side by side.

In order to implement the stepwise superposition method of the invention, each pixel in magnetic resonance imaging needs to provide an additional pixel point next to it to form a step. The scale of the k-space can be doubled or more than doubled by using the simple zero filling technique in Embodiment 2 of the invention or the more complicated total variation constrained data extrapolation method.

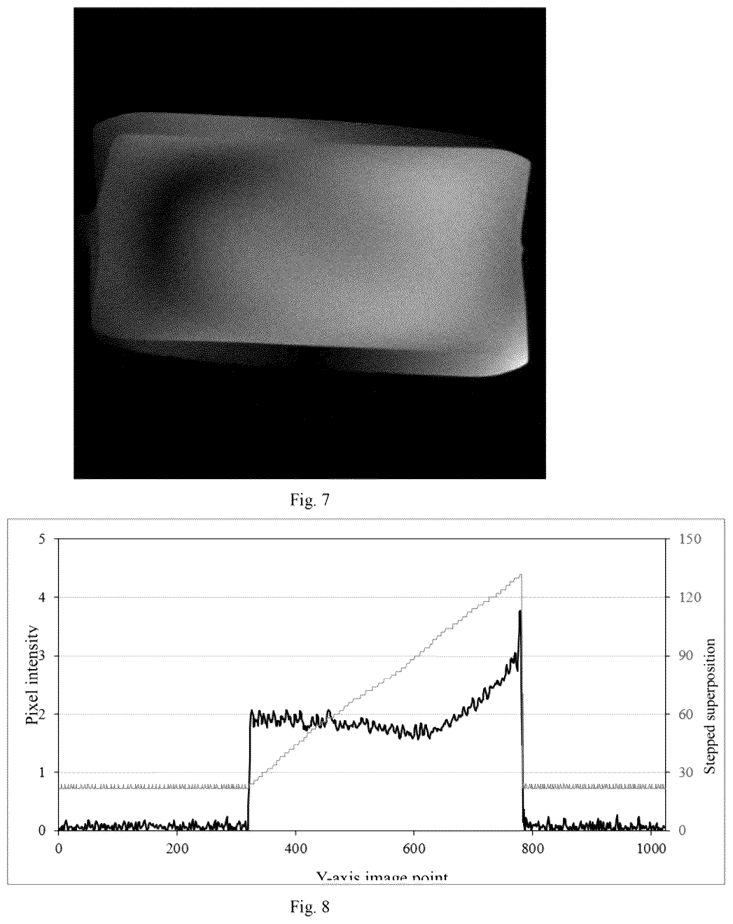

FIG. 7 is an image of an artificial membrane obtained from a Siemens Verio 3 T Tim nuclear magnetic resonance imager, with a pixel of 512×512. The main instruments and working parameters were: magnetic field 3 T, spin echo pulse sequence, layer thickness 4.0 mm, dwell time 15.6 μs, pulse repetition time 600 ms, echo time 6 ms, pixel bandwidth 250 Hz. The image obtained from Siemens RFHP software shows a ghost image. After the k-space is expanded to a 1024×1024 matrix by adding zeros and the ghost image is corrected, the stepwise superposition-based Fourier transform differentiation technique can be implemented.

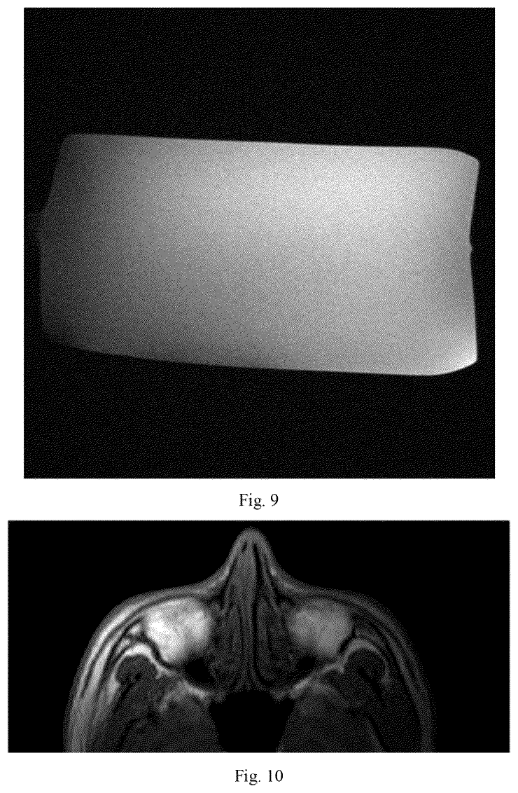

FIG. 8 shows a stepwise (right) superposition curve of 1024 pixels on the Y axis (gray thin solid line, plotted on the left ordinate) and a differential pixel curve (black thick solid line, plotted on the right ordinate). An initial step in FIG. 8 is not the zero step, but directly starts from the 22th step. Such a simple action saves the operation time of “negative” peak location and flattening when a pixel boundary is differentiated, because the calculation amount of digital imaging is far greater than spectrum plotting. FIG. 9 is an image of an artificial membrane obtained by the technique of the invention, which is true to the original data, eliminates the ghost image, and truly shows a smooth surface of the artificial membrane.

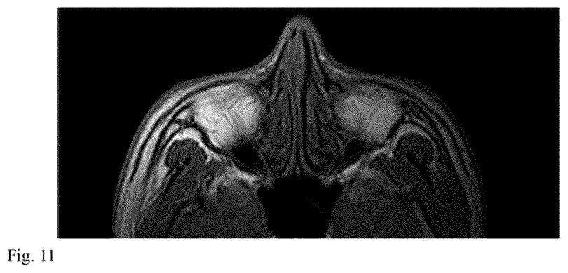

FIG. 10 is a magnetic resonance medical image from a volunteer's head obtained with a magnetic field of 1.5 T. The main working parameters were: layer thickness 6.0 mm, dwell time 7.2 ρs, pulse repetition time 480 ms, echo time 11.7 ms, pixel bandwidth 93 Hz. FIG. 11 shows that the recognizability of the original image of FIG. 10 is improved to the imaging level of a 3 T magnetic field after using the stepwise superposition-based Fourier transform differentiation technique of the invention.

Those skilled in the art will appreciate that the embodiments of the invention may be provided as methods, systems, or computer program products. Therefore, the invention may take the form of a full hardware embodiment, a full software embodiment, or an embodiment combining software and hardware aspects. Furthermore, the present application may take the form of a computer program product implemented on one or more computer usable storage media (including but not limited to magnetic disk memory, CD-ROM, optical memory, etc.) having computer usable program code embodied therein.

The invention is described with reference to flowcharts and/or block diagrams of the method, equipment (system), and computer program product according to the embodiments of the invention. It should be understood that each flow and/or block in the flowcharts and/or block diagrams, and combinations of flows and/or blocks in the flowcharts and/or block diagrams, may be implemented by computer program instructions. These computer program instructions may be provided to a processor of a general purpose computer, special purpose computer, embedded processor, or other programmable data processing apparatus to produce a machine, such that the instructions executed by the processor of the computer or other programmable data processing apparatus produce a device for implementing the functions specified in one or more flows in the flowcharts and/or one or more blocks in the block diagrams.

These computer program instructions may also be stored in a computer-readable memory which can direct a computer or other programmable data processing apparatus to function in a particular manner, such that the instructions stored in the computer-readable memory produce an article of manufacture including an instruction device which implements the functions specified in one or more flows in the flowcharts and/or one or more blocks in the block diagrams.

These computer program instructions may also be loaded onto a computer or other programmable data processing apparatus such that a series of operational steps are performed on the computer or other programmable apparatus to produce a computer implemented process, such that the instructions executed on the computer or other programmable apparatus provide steps for implementing the functions specified in one or more flows in the flowcharts and/or one or more blocks in the block diagrams.

The above embodiments are only preferred embodiments of the invention, and are not intended to limit the invention in other forms. Any person familiar with this field can make changes or modifications to equivalent embodiments with equivalent changes by using the above-mentioned technical contents. However, any simple amendments, equivalent changes and modifications made to the above embodiments according to the technical essence of the invention without departing from the content of the technical scheme of the invention still belong to the protection scope of the technical scheme of the invention.

What is claimed is:

1. A stepwise superposition-based Fourier transform differential method, comprising:
S1, sampling an analytic signal in a finite time domain, converting the analytic signal into a discrete spectrum, and identifying positions of spectral peak vertexes through a differential curve of the spectrum;
S2, superposing the peak vertexes in the spectrum in a stepped manner according to the principle of superposition-based Fourier transform; and
S3, differentiating the spectrum after the stepwise superposition to obtain a stepwise superposition-based Fourier transform differential spectrum or image.

2. The stepwise superposition-based Fourier transform differential method according to claim 1, wherein in the Step S1,
the analytic signal s(t) is discretized in a measurement period so as to take N samples, s(0), s(1), s(2), . . . , s(N−1), N frequency spectral data S(0), S(1), S(2), . . . , S(N−1) are obtained by discrete Fourier transform, and the Fourier transform matrix is expressed as follows:
$$[ \begin{matrix}S ( 0 ) \\ S ( 1 ) \\ S ( 2 ) \\ ⋮ \\ S ( N - 1 )\end{matrix} ] = [ \begin{matrix}1 & 1 & 1 & … & 1 \\ 1 & W & {W}^{2} & … & {W}^{N - 1} \\ 1 & {W}^{2} & {W}^{4} & … & {W}^{N - 2} \\ ⋮ & ⋮ & ⋮ & ⋱ & ⋮ \\ 1 & {W}^{N - 1} & {W}^{N - 2} & … & W\end{matrix} ] [ \begin{matrix}s ( 0 \\ s ( 1 ) \\ s ( 2 ) \\ ⋮ \\ s ( N - 1 )\end{matrix} ] \qquad ( 1 )$$
$$where W = exp ( - i 2 π / N ) ;$$
the Fourier transform spectrum S(ω) is multiplied by a diagonal matrix diag[aₖ]:
$$diag [ {a}_{k} ] \times [ S ( ω ) ] = [ \begin{matrix}0 & 0 & 0 & … & 0 & … & 0 \\ 0 & {a}_{1} & 0 & … & 0 & … & 0 \\ 0 & 0 & {a}_{2} & … & 0 & … & 0 \\ ⋮ & ⋮ & ⋮ & ⋱ & ⋮ & … & ⋮ \\ 0 & 0 & 0 & … & {a}_{k} & … & 0 \\ ⋮ & ⋮ & ⋮ & … & ⋮ & ⋱ & ⋮ \\ 0 & 0 & 0 & … & 0 & … & {a}_{N - 1}\end{matrix} ] [ \begin{matrix}S ( 0 ) \\ S ( 1 ) \\ S ( 2 ) \\ ⋮ \\ S ( k ) \\ ⋮ \\ S ( N - 1 )\end{matrix} ] \qquad ( 3 )$$
where if there are m overlapping peaks, the value of the diagonal element aₖ is 2n, n=4, 1, 2, . . . , m;
a stepwise superposition diagonal matrix is further written as:
$$diag [ {a}_{kk} ] = [ 0 … 0 {2}^{{ω}_{1}} … 2 {4}^{{ω}_{2}} … 4 {6}^{{ω}_{3}} … 6 {8}^{{ω}_{4}} … 80 … 0 ] \qquad ( 4 )$$
peak vertexes ω₁, ω₂, and ω₄ of the spectrum are located through discrimination of its second derivative.

3. The stepwise superposition-based Fourier transform differential method according to claim 1, wherein in the Step S2,
it is assumed that there are N overlapping peaks in the spectrum, that is, F₁, F₂, F₃, . . . , F_{N′}, the first peak F₁ is located on a zero step, whose peak intensity is multiplied by 2 according to a right superposition function, and the baseline is still the original spectral peak baseline 0; the peak intensity of the second peak F₂ is multiplied by 4 to rise to a first step, the third peak F₃ is multiplied by 6 to rise to a second step, . . . , the N^{th} peak F_{N} is multiplied by 2N to rise to a (N−1)^{th} step; when it comes to the last overlapping peak, returning to the zero step is conducted immediately, and then, the spectrum after the stepwise superposition is differentiated, so that the baseline of the superposition spectral line of the second peak returns to the first step after differentiation, which is marked as baseline 1; similarly, the remaining baselines are marked, and the baselines are connected to form a stepwise superposition-based Fourier transform differential spectrum.

4. The stepwise superposition-based Fourier transform differential method according to claim 1, wherein in the Step S3,
it is assumed that a peak vertex of the k^{th} overlapping peak is located at S(ωₖ), which becomes 2k^{S(ω}^{ₖ}⁾ after the stepwise superposition, and according to the differential rule of multiplied functions:
$$\frac{Δ [ 2 k S ( {ω}_{k} ) ]}{Δ ω} = \frac{Δ ( 2 k )}{Δ ω} S ( {ω}_{k} ) + 2 k \frac{Δ [ S ( {ω}_{k} ) ]}{Δ ω} = 2 S ( {ω}_{k} ) + 2 k \frac{Δ [ S ( {ω}_{k} ) ]}{Δ ω} \qquad ( 5 )$$
where Δ(2k)/Δω=2k−2(k−1)=2, which is equal to the difference from the previous (k−1)^{th} step; for all the following peak values S(ω) of the same step, 2k is a constant, that is, Δ(2k)=0:
$$\frac{Δ [ 2 k S ( ω ) ]}{Δ ω} = 2 k \frac{Δ [ S ( ω ) ]}{Δ ω} \qquad ( 6 )$$
(5) and (6) indicate that all points of the spectrum except the peak vertexes are processed into a spectral background by the differentiation.
